(19) United States
(12) Patent Application Publication
(10) Pub. No.: US 2022/0270937 A1
(43) Pub. Date: Aug. 25, 2022

(54) METHODS OF DETERMINING SHEAR STRENGTH OF BONDED FREE AIR BALLS ON WIRE BONDING MACHINES

(71) Applicant: Kulicke and Soffa Industries, Inc., Fort Washington, PA (US)

(72) Inventors: Gary S. Gillotti, North Wales, PA (US); Racheli Herskowits, Philadelphia, PA (US); Wei Qin, Ambler, PA (US)

(21) Appl. No.: 17/665,984

(22) Filed: Feb. 7, 2022

Related U.S. Application Data
(60) Provisional application No. 63/152,564, filed on Feb. 23, 2021.

(51) Int. Cl. H01L 21/66; H01L 23/00; G01N 3/24

(52) U.S. Cl. CPC H01L 22/12; H01L 24/45; G01N 3/24; H01L 2224/78343

(57) ABSTRACT

A method of determining a shear strength of a bonded free air ball on a wire bonding machine is provided. The method includes the steps of: (a) providing a free air ball at a working end of a wire bonding tool; (b) bonding the free air ball to a bonding location of a workpiece; (c) moving the wire bonding tool, while in contact with the bonded free air ball, in a direction along the bonding location; (d) monitoring wire bonding process signals during step (c); and (e) determining a shear strength using the wire bonding process signals monitored in step (d).

### CROSS REFERENCE TO RELATED APPLICATION

This application claims the benefit of U.S. Provisional Application No. 63/152,564, filed Feb. 23, 2021, the content of which is incorporated herein by reference.

### FIELD

The invention relates to wire bonding operations, and in particular, to techniques for determining a shear strength of a bonded free air ball on a wire bonding machine.

### BACKGROUND

In the processing and packaging of semiconductor devices, wire bonding continues to be a primary method of providing electrical interconnection between two locations within a package (e.g., between a die pad of a semiconductor die and a lead of a leadframe). More specifically, using a wire bonder (also known as a wire bonding machine) wire loops are formed between respective locations to be electrically interconnected. The primary methods of forming wire loops are ball bonding and wedge bonding. In forming the bonds between (a) the ends of the wire loop and (b) the bond site (e.g., a die pad, a lead, etc.), varying types of bonding energy may be used, for example, ultrasonic energy, thermosonic energy, thermocompressive energy, amongst others. Wire bonding machines (e.g., stud bumping machines) are also used to form conductive bumps from portions of wire.

In ball bonding, a free air ball is formed on an end of a wire (e.g., using an electronic flame off device), and then the free air ball is seated at the tip of a wire bonding tool. Then the seated free air ball is bonded to a bonding location (e.g., a bonding location on a workpiece, such as a bond pad on a semiconductor die). For example, the bonded free air ball may be a conductive bump bonded to the workpiece. In another example, the bonded free air ball may be a first bond of a wire loop bonded to the workpiece.

It is often desirable to know a shear strength of a bonded free air ball. Often, a shear strength of a bonded free air ball is measured offline (i.e., not on the wire bonding machine) using a destructive test. Unfortunately, such offline processes are inefficient from a number of perspectives, including as related to time and cost.

Thus, it would be desirable to provide improved methods for determining a shear strength of bonded free air balls on wire bonding machines.

### SUMMARY

According to an exemplary embodiment of the invention, a method of determining a shear strength of a bonded free air ball on a wire bonding machine is provided. The method includes the steps of: (a) providing a free air ball at a working end of a wire bonding tool; (b) bonding the free air ball to a bonding location of a workpiece; (c) moving the wire bonding tool, while in contact with the bonded free air ball, in a direction along the bonding location; (d) monitoring wire bonding process signals during step (c); and (e) determining a shear strength using the wire bonding process signals monitored in step (d).

### BRIEF DESCRIPTION OF THE DRAWINGS

The invention is best understood from the following detailed description when read in connection with the accompanying drawings. It is emphasized that, according to common practice, the various features of the drawings are not to scale. On the contrary, the dimensions of the various features are arbitrarily expanded or reduced for clarity. Included in the drawings are the following figures:

FIGS. 1A-1H are a series of block diagrams of portions of a wire bonding machine useful for illustrating a method of determining a shear strength of a bonded free air ball in accordance with various exemplary embodiments of the invention; and

FIG. 2 is a flow diagram illustrating a method of determining a shear strength of a bonded free air ball on a wire bonding machine in accordance with an exemplary embodiment of the invention.

### DETAILED DESCRIPTION

As used herein, the term “semiconductor element” is intended to refer to any structure including (or configured to include at a later step) a semiconductor chip or die. Exemplary semiconductor elements include a bare semiconductor die, a semiconductor die on a substrate (e.g., a leadframe, a PCB, a carrier, etc.), a packaged semiconductor device, a flip chip semiconductor device, a die embedded in a substrate, a stack of semiconductor die, amongst others. Further, the semiconductor element may include an element configured to be bonded or otherwise included in a semiconductor package (e.g., a spacer to be bonded in a stacked die configuration, a substrate, etc.). In connection with the invention, a semiconductor element is an example of a workpiece.

For wire bonding process optimization and/or verification, it may be important to determine the shear strength of a bonded free air ball before running full automatic production on a wire bonding machine. In accordance with various exemplary embodiments of the invention, methods of determining the shear strength of a bonded free air ball (i.e., the ball shear bond strength) on a wire bonding machine are provided. Such methods may be performed in real time (during continuous wire bonding processes) on a wire bonding machine. Such methods may be performed with little or no operator intervention, as the wire bonding machine may continue to run in an automatic mode after the shear strength is measured. This is a significant advantage over past practices where, after wire bonding, a workpiece is taken offline (away from the wire bonding machine) to measure the shear strength using an offline measurement tool.

For real time process monitoring, the measurements may be programmed to occur at predetermined intervals. For example, if the shear strength measurements exceed control limits, an alarm or warning may be sent, or the wire bonding process may be interrupted, and/or the wire bonding process may be changed automatically by closed loop control.

For example, if a shear strength measurement(s) exceed control limits (e.g., a measured shear strength value is not within an acceptable range), a correction can be implemented (e.g., closed loop correction) by varying one or more bonding parameters. Further, the measurements may be used to perform calibration of the wire bonding machine to improve consistency (i) when the wire is changed (e.g., wire spool changes), (ii) when the wire bonding tool is changed, and/or (iii) portability from one wire bonding machines to another (i.e., machine portability).

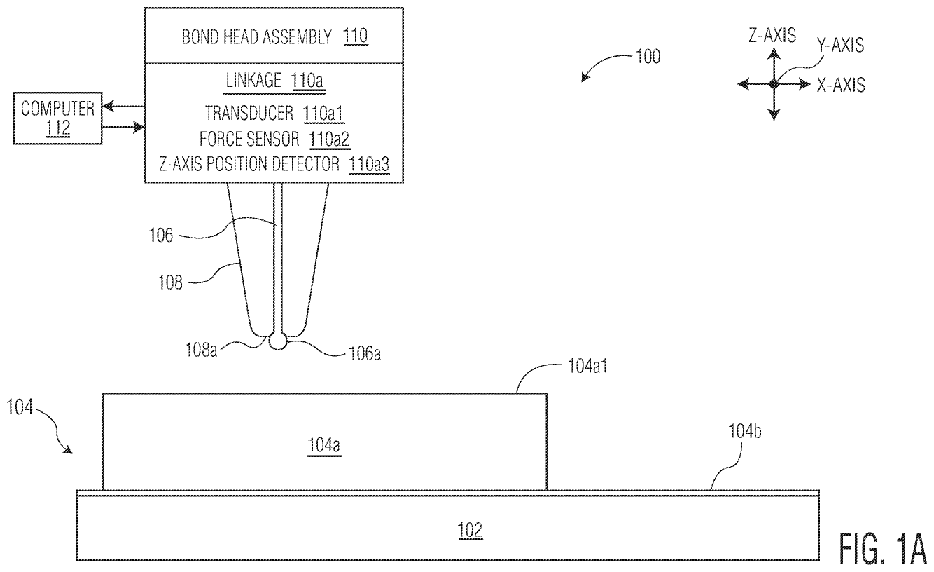

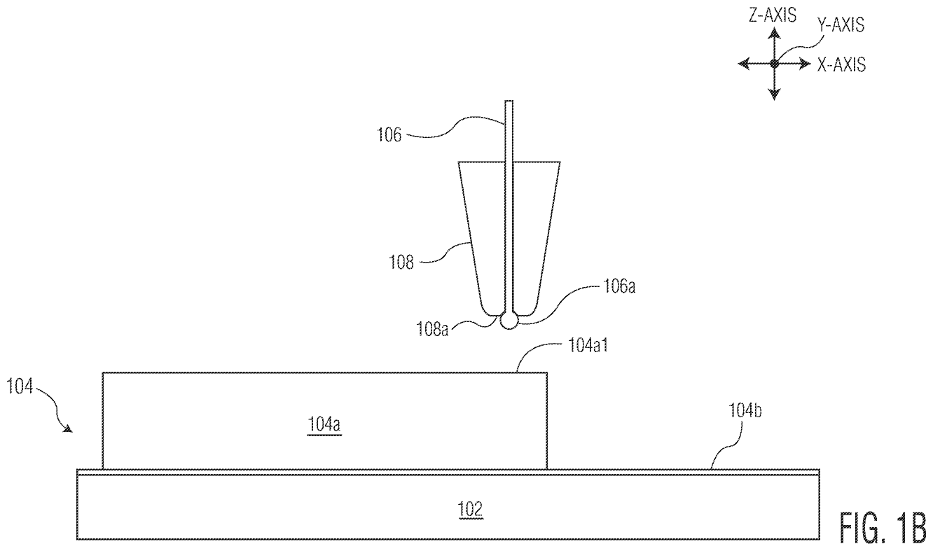

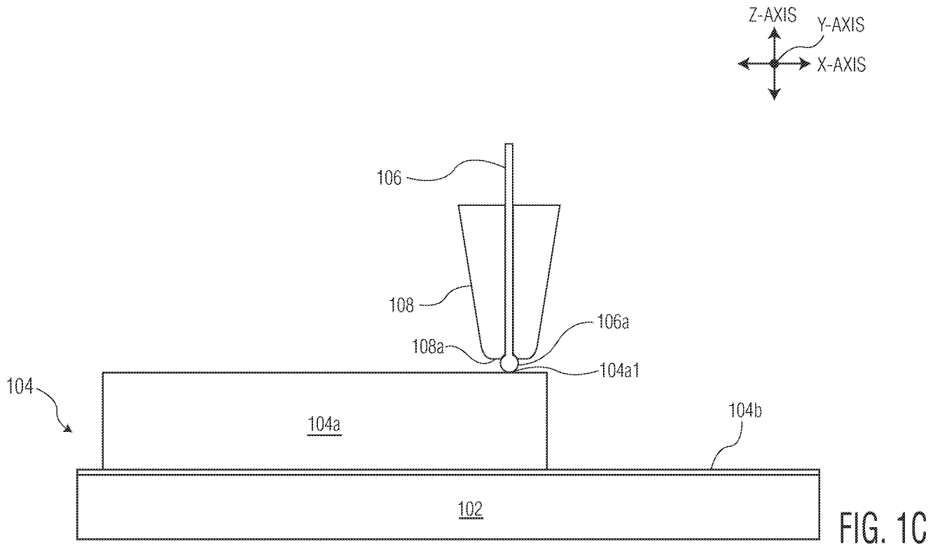

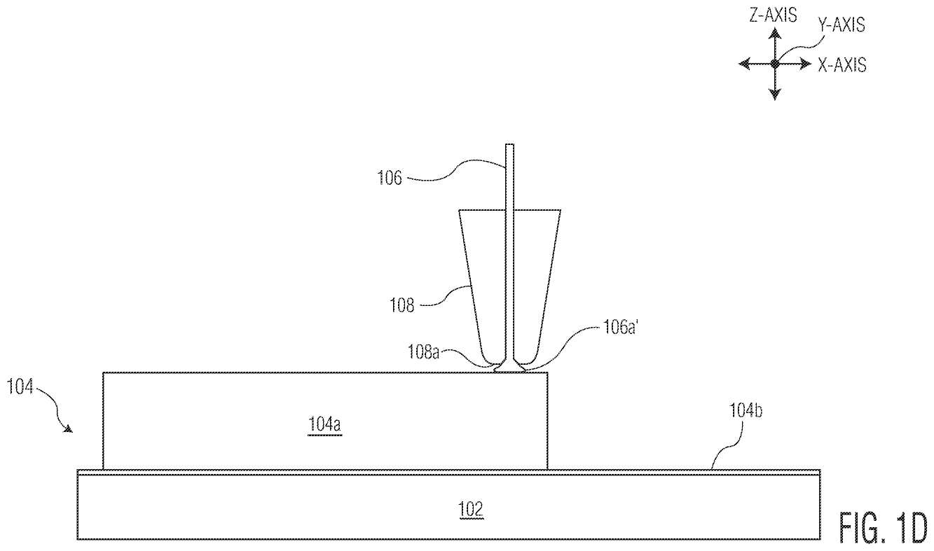

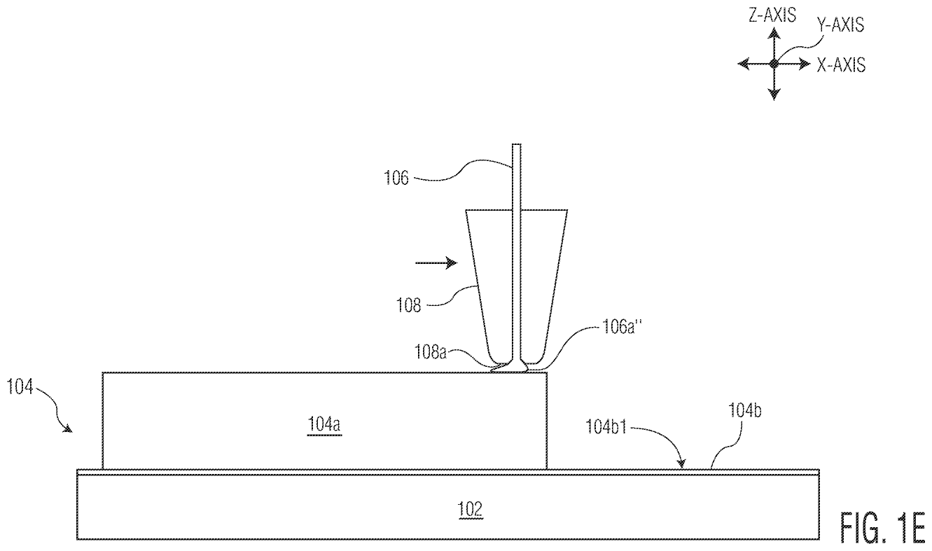

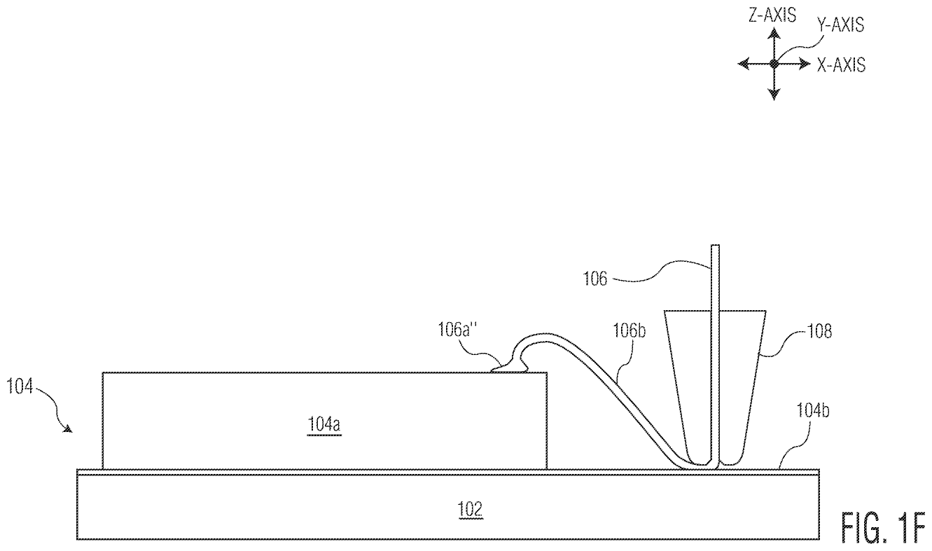

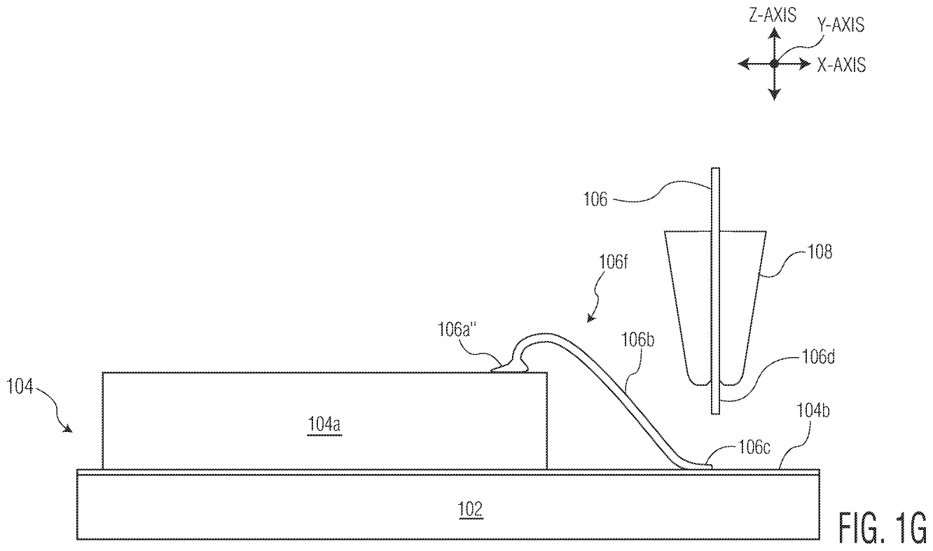

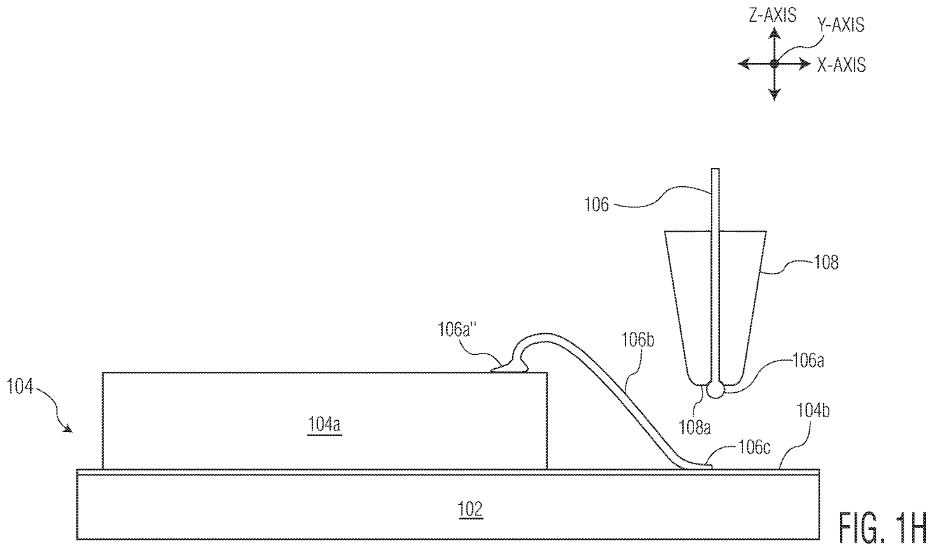

Referring now to FIGS. 1A-1H, a simplified wire bonding machine 100 is illustrated. Wire bonding machine 100 includes a support structure 102 (e.g., a heat block, an anvil, etc.) for supporting a workpiece 104 (e.g., where workpiece 104 is a semiconductor element). The exemplary workpiece 104 in FIGS. 1A-1H includes a semiconductor die 104a on a substrate 104b (such as a leadframe). Semiconductor die 104a includes a first bond location 104a1 (e.g., a bond pad of semiconductor die 104a).

As illustrated in FIG. 1A, wire bonding machine 100 also includes a bond head assembly 110 carrying a wire bonding tool 108 (e.g., a capillary wire bonding tool) for bonding wire portions (of a wire 106) to workpiece 104. Bond head assembly 110 includes a linkage 110a configured for movement along the z-axis of wire bonding machine 100. Additional elements included in bond head assembly 110 (and specifically carried by linkage 110a) include: a transducer 110a1 (e.g., an ultrasonic transducer); a force sensor 110a2; and a z-axis position detector 110a3. As will be appreciated by those skilled in the art, wire bonding tool 108 (carried by bond head assembly 110) is moveable along a plurality of axes of wire bonding machine 100 to perform wire bonding operations. For example, wire bonding tool 108 is moved along an x-axis and a y-axis of wire bonding machine 100 through movement of bond head assembly 110, and wire bonding tool 108 is moved along a z-axis of wire bonding machine 100 through movement of linkage 110a.

Transducer 110a1 carries wire bonding tool 108, and provides ultrasonic scrub at a working end 108a of wire bonding tool 108 (also known as the tip portion of wire bonding tool 108). Force sensor 110a2 senses a bonding force (e.g., along the z-axis) applied during wire bonding operations. Z-axis position detector 110a3 (e.g., a z-axis encoder) detects the z-axis position of linkage 110a (and hence a relative z-axis position of wire bonding tool 108), and provides data corresponding to this z-axis position (e.g., real time) to a computer 112 of wire bonding machine 100. Thus, computer 112 has information related to the z-axis position of wire bonding tool 108 through its motions. Further, certain information from (and/or related to) each of transducer 110a1 and force sensor 110a2 may be provided to computer 112 (as shown by the arrow extending from bond head assembly 110 to computer 112). Computer 112 may also provide information (e.g., instructions) back to elements of bond head assembly 110 (as shown by the arrow extending from computer 112 to bond head assembly 110). In a specific example, in a closed loop configuration, computer 112 provides control signals (e.g., current signals) to transducer 110a1. In FIG. 1A, a free air ball 106a (i.e., a portion of wire 106) is seated at working end 108a of wire bonding tool 108.

In connection with FIGS. 1B-1H, various elements of wire bonding machine 100 (e.g., computer 112 and elements of bond head assembly 110) have been removed for simplicity. In FIG. 1B, wire bonding tool 108 has been moved (through movement of bond head assembly 110, see FIG. 1A) such that free air ball 106a is located substantially above a first bond location 104a1 on a surface of semiconductor die 104a. In FIG. 1C, wire bonding tool 108 has been lowered such that free air ball 106a is in contact with first bond location 104a1. In FIG. 1D, free air ball 106a has been ultrasonically bonded to first bond location 104a1 to form a bonded free air ball 106a′ (e.g., also referred to as a bonded ball, or a first bond of a wire loop).

Referring now to FIG. 1E, wire bonding tool 108 is moved, while in contact with bonded free air ball 106a′, in a direction along first bond location 104a1. For example, in connection with this motion, wire bonding tool 108 may be moved in a direction (e.g., a substantially horizontal direction, a horizontal direction, an x-axis direction, etc.) that is substantially parallel to a bonding surface of first bond location 104a1.

This movement of wire bonding tool 108 shown in FIG. 1E induces a force (e.g., a shear force) into bonded free air ball 106a′, resulting in deformation of bonded free air ball 106a′ (illustrated in FIG. 1E as deformed bonded free air ball 106a″). While FIG. 1E illustrates deformation of bonded free air ball 106a′ resulting from the movement of wire bonding tool 108, this is simply an illustration of an exemplary deformation. That is, different types of deformation, or no deformation at all (e.g., the capillary may drag across bonded free air ball 106a′ without deformation thereof), may result from the movement of wire bonding tool 108. In another example, bonded free air ball 106a′ may separate from first bond location 104a1, and then be rebonded to first bond location 104a1—all as a result of the movement of wire bonding tool 108.

In connection with the motion of wire bonding tool 108 shown in FIG. 1E, certain wire bonding process signals are monitored. For example, the monitored wire bonding process signals may include at least one of (i) an electrical characteristic of ultrasonic transducer 110a1 carrying wire bonding tool 108, (ii) a bonding force signal provided by force sensor 110a2 of bond head assembly 110, (iii) a force feedback signal related to a bonding force applied by wire bonding tool 108, and (d) a z-axis position signal (e.g., as provided by z-axis position detector 110a3).

One or more of the wire bonding process signals may be monitored at different times in connection with the movement of wire bonding tool 108 shown in FIG. 1E. For example, one or more of the wire bonding process signals may be monitored: at a time just prior to the movement of wire bonding tool 108 shown in FIG. 1E; during the movement of wire bonding tool 108 shown in FIG. 1E; and at a time immediately after the movement of wire bonding tool 108 shown in FIG. 1E.

Referring now to FIG. 1F, wire bonding tool 108 has been moved to a second bond location 104b1 (e.g., a bonding location of substrate 104b, such as a lead of a leadframe) to perform a second bond operation. Through this bonding operation, a second bond 106c is created. While moving wire bonding tool 108 from the position shown in FIG. 1E to the position shown in FIG. 1F, a length of wire 106b is extended between first bond location 104a1 and second bond location 104b1 (see second bond location identified in FIG. 1E).

After formation of second bond 106c in FIG. 1F, wire bonding tool 108 is moved away from second bond 106c as shown in FIG. 1G. Through this motion, wire 106 (engaged with wire bonding tool 108) is separated from a wire loop 106f. Wire loop 106f includes bonded free air ball 106a″, second bond 106c, and length or wire 106b therebetween. A wire tail 106d now extends from working end 108a of wire bonding tool 108. In FIG. 1H, a subsequent free air ball 106a is formed using wire tail 106d. This subsequent free air ball 106a may be used to repeat the process shown above in connection with FIGS. 1A-1G.

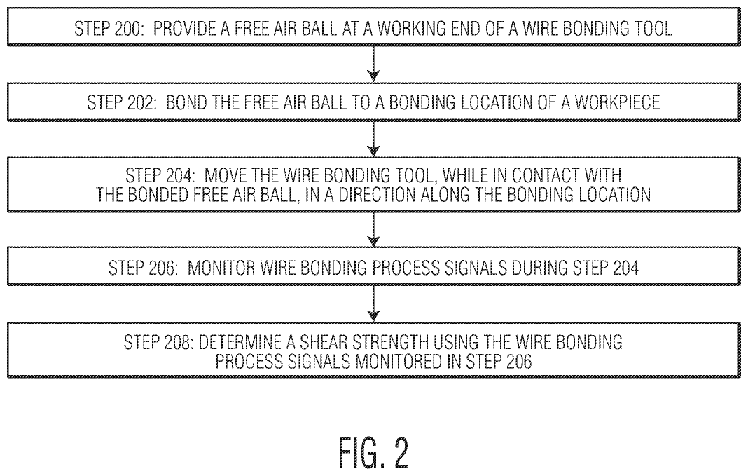

FIG. 2 is a flow diagram illustrating an exemplary method of determining a shear strength of a bonded free air ball on a wire bonding machine. As is understood by those skilled in the art, certain steps included in the flow diagram may be omitted; certain additional steps may be added; and the order of the steps may be altered from the order illustrated—all within the scope of the invention.

At Step 200, a free air ball is provided at a working end of a wire bonding tool (e.g., see FIG. 1A). At Step 202, the free air ball is bonded to a bonding location of a workpiece (e.g., see FIGS. 1C-1D). At Step 204, the wire bonding tool is moved, while in contact with the bonded free air ball, in a direction along the bonding location (e.g., see FIG. 1E). This motion of the wire bonding tool, and its effect of the bonded free air ball, may be termed “ball shear motion”. In specific examples, after the free air ball is bonded to the bonding location, the wire bonding tool is moved along the bonding location (e.g., along a bond pad) a distance of between: 4-12 micrometers; or between 6-10 micrometers. This distance, of course, may vary depending on factors such as wire material type, wire diameter, free air ball diameter, etc. During this motion, a z-axis force (e.g., provided by a z-axis motor, not specifically shown but understood by those skilled in the art) and/or ultrasonic energy may be applied.

At Step 206, wire bonding process signals are monitored during Step 204 (ones of such wire bonding process signals may also be monitored just before Step 206 and/or just after Step 206). The next four paragraphs of this application provide examples of such wire bonding process signals; however, it is understood that additional and/or different wire bonding process signals may be utilized in the determination of the shear strength.

An exemplary wire bonding process signal that may be monitored in Step 206 (and/or just before Step 206, and/or just after Step 206) includes an electrical characteristic of an ultrasonic transducer carrying the wire bonding tool. Examples of such electrical characteristics of the ultrasonic transducer may include an impedance (e.g., an ultrasonic impedance) seen by the ultrasonic transducer, an electrical voltage applied to the ultrasonic transducer, and/or an electrical current applied to the ultrasonic transducer. As is known to those skilled in the art, impedance may be determined by knowing the electrical voltage and the electrical current.

Another exemplary wire bonding process signal that may be monitored in Step 206 (and/or just before Step 206, and/or just after Step 206) includes a bonding force signal provided by a force sensor of a bond head of the wire bonding machine. For example, FIG. 1A illustrates force sensor 110a2 of bond head assembly 110. In this example, this is a z-axis force sensor, which monitors the bonding force applied to workpiece 104. While this measures a z-axis force in this example, it is understood that the bonding force may have other force components (e.g., a y-axis component, an x-axis component, etc.).

Yet another exemplary wire bonding process signal that may be monitored in Step 206 (and/or just before Step 206, and/or just after Step 206) includes a force feedback signal related to a bonding force applied. For example, and as will be appreciated by those skilled in the art, such a force feedback signal may be an electrical current signal applied to a z-axis motor for driving the bond head assembly along the z-axis. Such an electrical current signal may vary, for example, because of free air ball deformation and/or movement of the workpiece.

Yet another exemplary wire bonding process signal that may be monitored in Step 206 (and/or just before Step 206, and/or just after Step 206) includes a z-axis position signal (e.g., provided by z-axis position detector 110a3 in FIG. 1A). Such a z-axis position detector (e.g., a z-axis encoder) is used to measure deformation during bonding of a free air ball (or other deformation) and may also be used to provide information about shearing of a bonded free air ball.

At Step 208, a shear strength is determined using the wire bonding process signals monitored in Step 206.

The shear strength may be determined using a calculation, for example, in connection with historical data. In a specific example, actual shear strength values may be measured (manually) while collecting wire bonding process signals. This information (e.g., historical data) may be stored in connection with one or more data structures. Such data structures may reside on (or be accessible to) a computer of a wire bonding machine. In the actual determination (e.g., calculation) of a shear strength value, different weighting may be applied to different wire bonding process signals. That is, depending on the application (e.g., the wire material being used, the wire diameter being used, the wire bonding parameters, etc.), one or more of the wire bonding process signals may be more (or less) relevant in the determination of the shear strength.

As will be appreciated by those skilled in the art, a single shear strength value may be determined for a single bonded free air ball. However, the invention is not limited thereto. For example, each of Steps 200-208 may be repeated for a plurality of bonded free air balls to determine the shear strength (e.g., for each of the plurality of bonded free air balls, to create a matrix of shear strengths, etc.). Then, a single shear strength value may be determined utilizing the shear strength determined for each of the plurality of bonded free air balls (e.g., by averaging the shear strengths determined for each of the plurality of bonded free air balls).

In connection with aspects of the invention, the shear strength is determined for purposes of calibration (e.g., to make sure that the wire bonding process will run as planned during production). In such cases, the inventive methods (e.g., the method shown in FIG. 2) may be performed: at a predetermined interval; after the wire bonding tool on the wire bonding machine is changed; and/or after a bonding wire supply (e.g., a wire spool) on the wire bonding machine is changed.

Although the invention is illustrated and described herein with reference to specific embodiments, the invention is not intended to be limited to the details shown. Rather, various modifications may be made in the details within the scope and range of equivalents of the claims and without departing from the invention.

What is claimed:

1. A method of determining a shear strength of a bonded free air ball on a wire bonding machine, the method comprising the steps of:
(a) providing a free air ball at a working end of a wire bonding tool;
(b) bonding the free air ball to a bonding location of a workpiece;
(c) moving the wire bonding tool, while in contact with the bonded free air ball, in a direction along the bonding location;
(d) monitoring wire bonding process signals during step (c); and
(e) determining a shear strength using the wire bonding process signals monitored in step (d).

2. The method of claim 1 wherein the wire bonding process signals monitored in step (d) include at least one of (i) an electrical characteristic of an ultrasonic transducer carrying the wire bonding tool, (ii) a bonding force signal provided by a force sensor of a bond head assembly of the wire bonding machine, (iii) a force feedback signal related to a bonding force applied, and (d) a z-axis position signal.

3. The method of claim 1 wherein the wire bonding process signals monitored in step (d) include an electrical characteristic of an ultrasonic transducer carrying the wire bonding tool.

4. The method of claim 3 wherein the electrical characteristic is related to an impedance of the ultrasonic transducer.

5. The method of claim 1 wherein the wire bonding process signals monitored in step (d) include a bonding force signal provided by a force sensor of a bond head assembly of the wire bonding machine.

6. The method of claim 1 wherein the wire bonding process signals monitored in step (d) include a force feedback signal related to a bonding force applied.

7. The method of claim 1 wherein the wire bonding process signals monitored in step (d) include a z-axis position signal.

8. The method of claim 1 wherein step (d) also includes monitoring wire bonding process signals during at least one of (i) a time just prior to step (c), and (ii) a time immediately after step (c).

9. The method of claim 1 wherein step (d) also includes monitoring wire bonding process signals at a time just prior to step (c).

10. The method of claim 1 wherein step (d) also includes monitoring wire bonding process signals during a time immediately after step (c).

11. The method of claim 1 wherein step (d) also includes monitoring wire bonding process signals during (i) a time just prior to step (c), and (ii) a time immediately after step (c).

12. The method of claim 1 wherein step (d) also includes monitoring at least one of the wire bonding process signals at a time just prior to step (c), at least one of the wire bonding signals during step (c), and at least one of the wire bonding signals at a time immediately after step (c).

13. The method of claim 1 wherein each of steps (a)-(e) are repeated for a plurality of bonded free air balls to determine the shear strength.

14. The method of claim 13 wherein a single shear strength value is determined by averaging the shear strength determined for each of the plurality of bonded free air balls.

15. The method of claim 13 wherein a single shear strength value is determined utilizing the shear strength determined for each of the plurality of bonded free air balls.

16. The method of claim 1 wherein each of steps (a)-(e) are performed at a predetermined interval.

17. The method of claim 1 wherein each of steps (a)-(e) are performed after the wire bonding tool on the wire bonding machine is changed.

18. The method of claim 1 wherein each of steps (a)-(e) are performed after a bonding wire supply on the wire bonding machine is changed.

19. The method of claim 1 further comprising the step of (f) extending a length of wire from the bonding location to another bonding location to form a wire loop between the bonding location and the another bonding location.

20. The method of claim 19 wherein step (f) occurs after step (d).

21. The method of claim 19 wherein step (f) includes bonding the length of wire to the second bonding location to complete the wire loop.

22. The method of claim 21 wherein step (f) also includes separating the wire loop from a wire supply of the wire bonding machine.

23. The method of claim 22 further comprising the step of (g) providing a wire tail at the working end of the wire bonding tool after the step of separating.

24. The method of claim 23 wherein another free air ball is formed using the wire tail, and steps (b)-(e) are repeated using the another free air ball.
